(19) United States
(12) Patent Application Publication
(10) Pub. No.: US 2026/0371638 A1
(43) Pub. Date: Nov. 19, 2026

(54) SEMICONDUCTOR DEVICE INCLUDING DUAL-GATE STRUCTURE AND TWO-DIMENSIONAL CHANNEL LAYER

(71) Applicant: Samsung Electronics Co., Ltd., Suwon-si (KR)

(72) Inventors: Donghoon Hwang, Suwon-si (KR); Seongkwang Kim, Suwon-si (KR); Hyunsoo Kim, Suwon-si (KR); Jina Kim, Suwon-si (KR)

(21) Appl. No.: 19/640,139

(22) Filed: Apr. 6, 2026

(30) Foreign Application Priority Data
May 15, 2025 (KR) 10-2025-0063297

(51) Int. Cl. H10D 30/47; H10D 30/00; H10D 62/17; H10D 62/80; H10D 64/27; H10D 84/01; H10D 84/83; H10D 62/10; H10D 64/62

(52) U.S. Cl. CPC H10D 30/481; H10D 30/503; H10D 62/292; H10D 62/883; H10D 64/518; H10D 84/0135; H10D 84/0151; H10D 84/832; H10D 62/121; H10D 62/122; H10D 64/62

(57) ABSTRACT

A semiconductor device may include: a substrate; a gate separation structure extending in a first direction on the substrate; gate structures extending in a second direction, intersecting the first direction, on the substrate and spaced apart from each other by the gate separation structure, in the second direction; a source/drain electrode structure on at least one side of each of the gate structures; spacer layers between the gate structures and the source/drain electrode structures; and channel layers surrounded by each of the gate structures and extending into the spacer layers to contact the source/drain electrode structures. Each of the gate structures may include: a first electrode including a first portion and first protrusion portions extending from the first portion and protruding toward the gate separation structure; and a second electrode including a second portion and second protrusion portions extending from the second portion and protruding between the first protrusion portions.

### CROSS-REFERENCE TO RELATED APPLICATION

This application claims benefit of priority to Korean Patent Application No. 10-2025-0063297 filed on May 15, 2025, in the Korean Intellectual Property Office, the disclosure of which is incorporated herein by reference in its entirety.

### BACKGROUND

As miniaturization is advanced to improve the integration of semiconductor devices, research using two-dimensional materials has been conducted recently for this purpose. Two-dimensional materials may refer to crystal materials within a few atomic layers and has been researched as materials to replace silicon. Furthermore, two-dimensional materials are stable and have excellent characteristics even in nanoscale thicknesses, and attracts attention as next-generation materials that may overcome the performance degradation problem due to miniaturization of semiconductor devices.

### SUMMARY

The present disclosure relates to semiconductor devices, and specifically relates to semiconductor devices including a channel layer including a two-dimensional material.

Aspects of the present disclosure provide semiconductor devices with improved integration and electrical characteristics.

However, the object of the present disclosure is not limited to the above-described objects, and may be variously expanded without departing from the spirit and domain of the present disclosure.

A semiconductor device according to example implementations of the present disclosure may include: a substrate; a gate separation structure extending in a first direction on the substrate; gate structures extending in a second direction, intersecting the first direction, on the substrate and spaced apart from each other by the gate separation structure, in the second direction; source/drain electrode structures on at least one side of each of the gate structures; spacer layers between the gate structures and the source/drain electrode structures; and channel layers extending into the spacer layers, thereby contacting the source/drain electrode structures, wherein each of the gate structures is around a periphery of the channel layers, wherein each of the gate structures includes: a first electrode including: a first portion, and first protrusion portions extending from the first portion and protruding toward the gate separation structure, wherein the first protrusion portions are spaced apart from each other in a vertical direction intersecting the first direction and the second direction; and a second electrode including: a second portion, and second protrusion portions extending from the second portion and protruding between the first protrusion portions, wherein the second protrusion portions are spaced apart from each other in the vertical direction, wherein each of the channel layers extends between the first electrode and the second electrode.

A semiconductor device of example implementations of the present disclosure may include: a substrate; first gate structures spaced apart from each other on the substrate in a first direction and extending in a second direction, intersecting the first direction, each of the first gate structures including: a first electrode including first protrusion portions, and a second electrode including second protrusion portions alternately stacked with the first protrusion portions in a vertical direction; a first source/drain electrode structure between the first gate structures and extending in the second direction; first spacer layers on both sides of the first source/drain electrode structure; first channel layers between each of the first protrusion portions and each of the second protrusion portions, the first channel layers extending in the first direction and extending into the first spacer layers, thereby contacting the first source/drain electrode structure; a first gate dielectric liner between each of the first protrusion portions and each of the first channel layers; and a second gate dielectric liner between each of the second protrusion portions and each of the first channel layers.

A semiconductor device according to example implementations of the present disclosure may include: a substrate; a gate separation structure extending in a first direction on the substrate; gate structures extending in a second direction, intersecting the first direction, on the substrate and spaced apart from each other by the gate separation structure in the second direction, each of the gate structures including first protrusion portions and second protrusion portions disposed alternately with the first protrusion portions; a source/drain electrode structure on at least one side of each of the gate structures; spacer layers between the gate structures and the source/drain electrode structure; a first gate dielectric liner covering a side surface, an upper surface, and a lower surface of each of the first protrusion portions; a second gate dielectric liner covering a side surface, an upper surface, and a lower surface of each of the second protrusion portions; and a channel layer between the first gate dielectric liner and the second gate dielectric liner and in contact with the first gate dielectric liner and the second gate dielectric liner, wherein a thickness of the first gate dielectric liner is greater than a thickness of the channel layer, wherein a thickness of the second gate dielectric liner is greater than the thickness of the channel layer, and wherein the channel layer includes a transition metal dichalcogenide (TMD) material.

A semiconductor device according to example implementations of the present disclosure may include: a dual gate structure including a first electrode including first protrusion portions and a second electrode including second protrusion portions alternating in a direction, perpendicular to the first protrusion portions, and a two-dimensional channel layer between the first electrode and the second electrode. Accordingly, since an effective cross-sectional area of the two-dimensional channel layer may be secured, a semiconductor device having improved integration and electrical characteristics may be provided.

However, the effects of the present disclosure are not limited to the effects described above, and may be expanded in various manners without departing from the spirit and scope of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to example implementations of the present disclosure;

FIG. 2A is a cross-sectional view taken along line I-I’ of the semiconductor device illustrated in FIG. 1 according to an example implementation;

FIG. 2B is a cross-sectional view taken along line II-II’ of the semiconductor device illustrated in FIG. 1 according to an example implementation;

FIG. 2C is a cross-sectional view taken along line III-III’ of the semiconductor device illustrated in FIG. 1 according to an example implementation;

FIG. 3A is an enlarged view of an example implementation of region A of the semiconductor device of FIG. 2A;

FIGS. 3B and 3C are enlarged views of other example implementations of region A of the semiconductor device of FIG. 2A;

FIG. 4A is a cross-sectional view taken along line I-I’ of the semiconductor device illustrated in FIG. 1 according to another example implementation;

FIG. 4B is a cross-sectional view taken along line II-II’ of the semiconductor device illustrated in FIG. 1 according to another example implementation;

FIG. 5 is a cross-sectional view taken along line Ⅱ-Ⅱ’ of the semiconductor device illustrated in FIG. 1 according to another example implementation; and

FIGS. 6A, 6B, 7, 8A, 8B, 9A, 9B, 10A, 10B, 11, 12A, 12B, 13A, 13B, 14, 15, 16A, 16B, 17, 18A, and 18B are views illustrating a process sequence illustrating a method of manufacturing a semiconductor device according to an example implementation of the present disclosure.

### DETAILED DESCRIPTION

Hereinafter, example implementations of the present disclosure will be described with reference to the accompanying drawings. For identical components on a drawing, the same reference numerals are used, and duplicate descriptions of identical components are omitted.

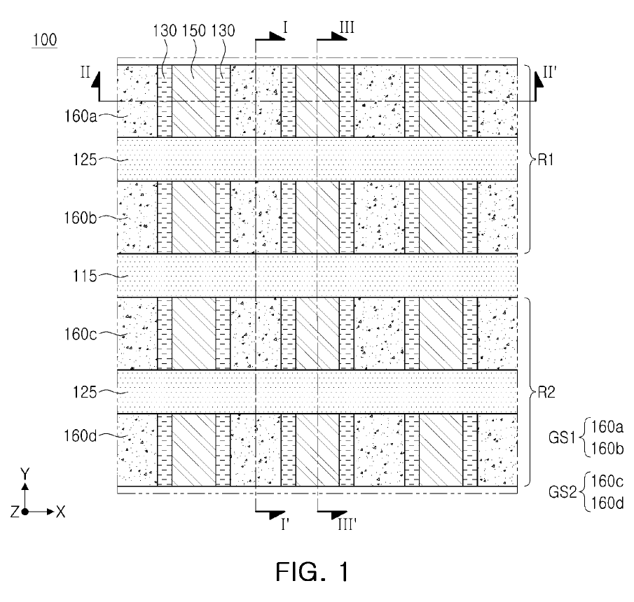

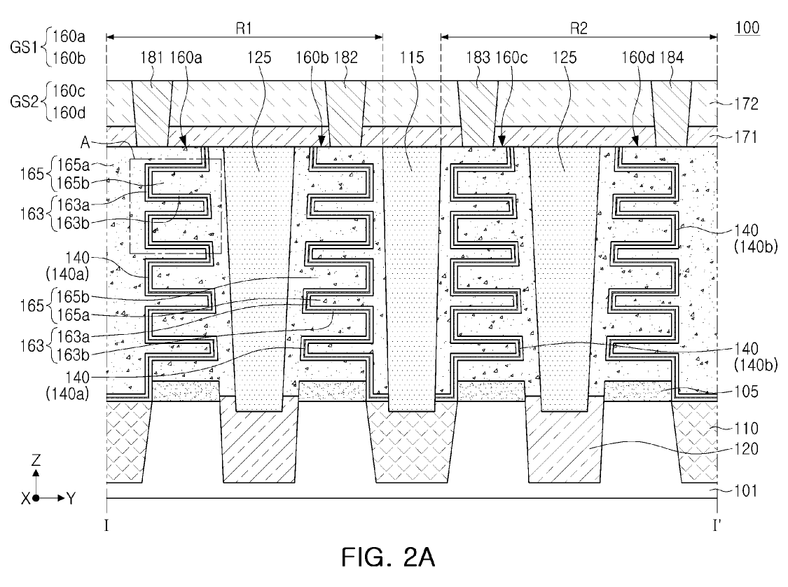

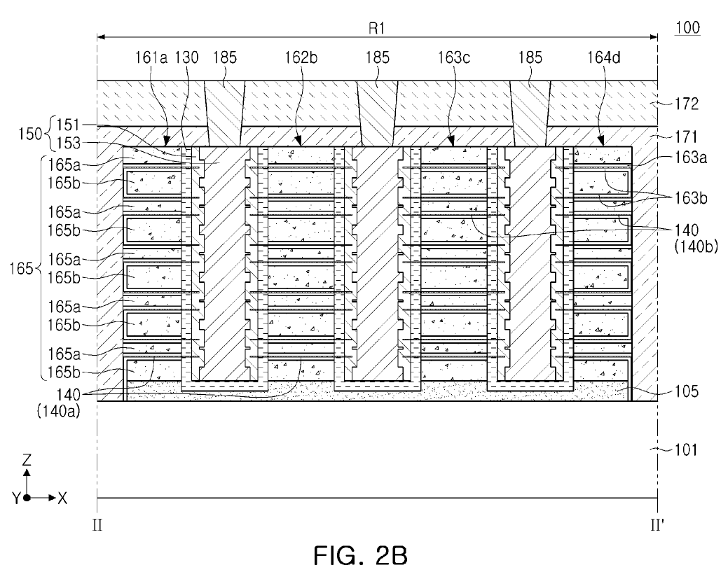

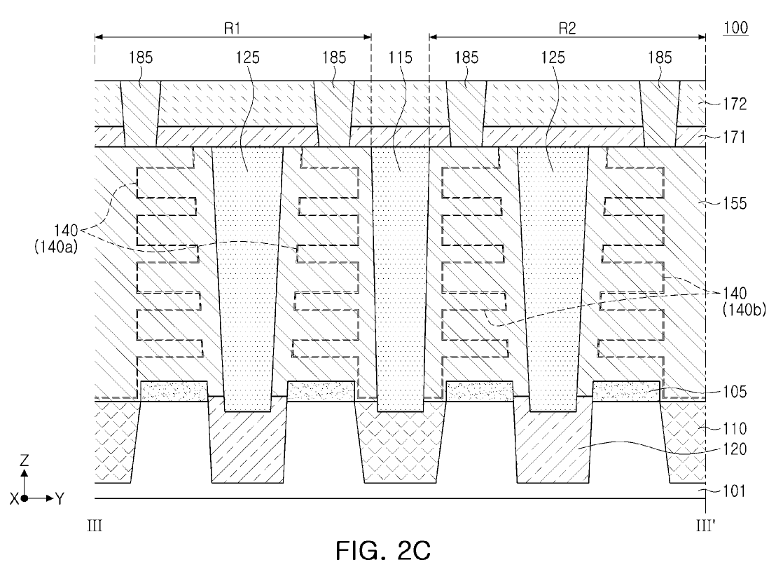

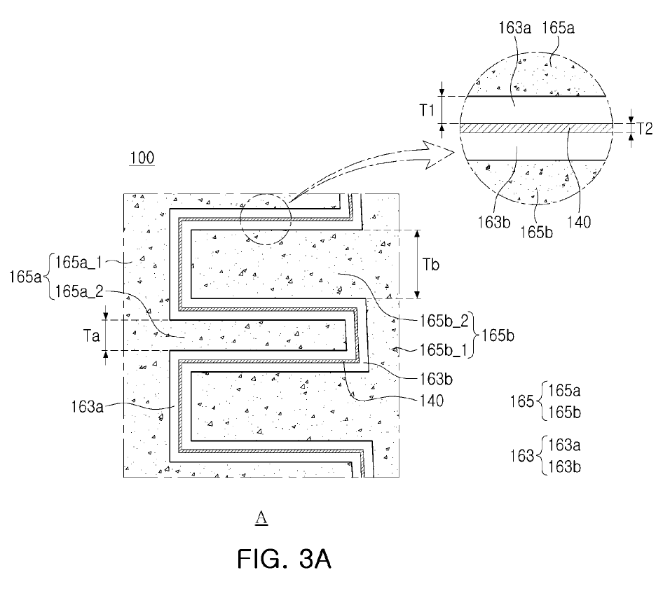

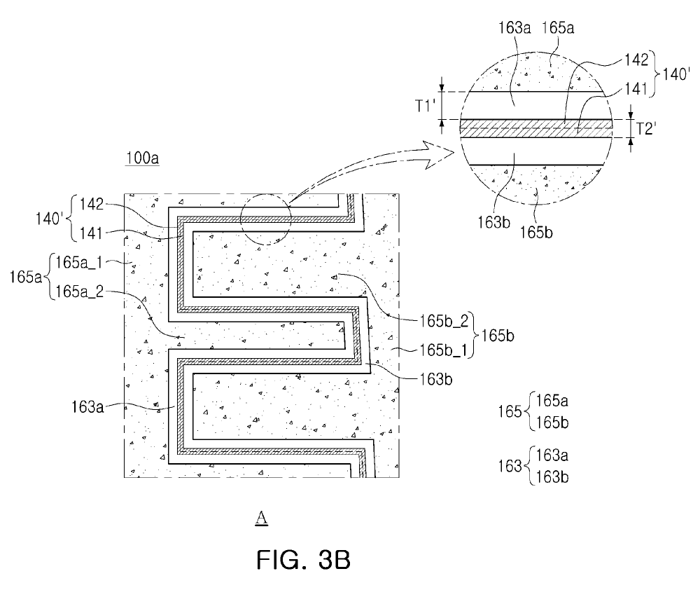

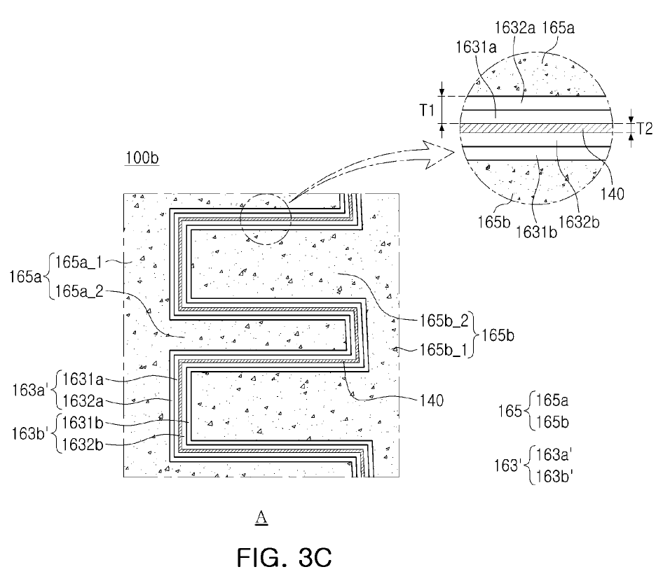

FIG. 1 is a plan view illustrating a semiconductor device according to example implementations of the present disclosure. FIG. 2A is a cross-sectional view taken along line I-I’ of the semiconductor device illustrated in FIG. 1 according to an example implementation. FIG. 2B is a cross-sectional view taken along line II-II’ of the semiconductor device illustrated in FIG. 1 according to an example implementation. FIG. 2C is a cross-sectional view taken along line III-III’ of the semiconductor device illustrated in FIG. 1 according to an example implementation. FIG. 3A is an enlarged view of an example implementation of region A of the semiconductor device of FIG. 2A. For convenience of explanation, only some components of a semiconductor device are illustrated in FIG. 1.

Referring to FIGS. 1, 2A, 2B and 2C, a semiconductor device 100 may include a substrate 101 including a first region R1 and a second region R2, a first element isolation film 110 disposed within the substrate 101 and extending in a first direction (X-direction), second element isolation films 120 disposed within the substrate 101 and spaced apart from each other in a second direction (Y-direction) with the first element isolation film 110 interposed therebetween, a first gate separation structure 115 disposed on the first element isolation film 110 between the first region R1 and the second region R2 and extending in the first direction (X-direction), and a second gate separation structure 125 disposed on the second element isolation films 120 and extending in the first direction (X-direction).

The semiconductor device 100 may include first gate structures GS1 disposed on the first region R1, second gate structures GS2 disposed on the second region R2, channel layers 140, source/drain electrode structures 150 disposed on at least one side of each of the first and second gate structures GS1 and GS2, and spacer layers 130 disposed between the first and second gate structures GS1 and GS2 and the source/drain electrode structures 150. The semiconductor device 100 may further include insulating patterns 105 disposed on an upper surface of the substrate 101 exposed by the first and second element isolation films 110 and 120. The substrate 101 may include a group IV semiconductor such as Si or Ge, a group IV-IV compound semiconductor such as SiGe or SiC, or a group III-V compound semiconductor such as GaAs, InAs, or InP.

The first region R1 and the second region R2 may be regions separated from each other with the first gate separation structure 115 as a center, which will be described below. The first region R1 and the second region R2 may be arranged in the second direction (Y-direction) with the first gate separation structure 115 as the center. For example, the first region R1 may be a region of the substrate 101 defined on one side of the first gate separation structure 115, and the second region R2 may be another region of the substrate 101 defined on the other side of the first gate separation structure 115. The first gate separation structure 115 described herein may be referred to as an element isolation structure.

Transistors having different conductivity types may be formed in the first region R1 and the second region R2. In one example, the first region R1 may be a region in which an N-type transistor (nFET) is disposed, and the second region R2 may be a region in which a P-type transistor (pFET) is disposed. However, the present disclosure is not limited thereto, and transistors having the same conductivity type may be formed in the first region R1 and the second region R2.

The first and second element isolation films 110 and 120 may be disposed within the substrate 101. The first and second element isolation films 110 and 120 may be formed, for example, by a shallow trench isolation (STI) process. The first element isolation film 110 may extend in the first direction (X-direction) between the first region R1 and the second region R2, and each of the second element isolation films 120 may extend in the first direction (X-direction) in the first region R1 and the second region R2. The second element isolation films 120 may be spaced apart from each other in the second direction (Y-direction) with the first element isolation film 110 interposed therebetween.

A width of each of the first and second element isolation films 110 and 120 in the second direction (Y-direction) may become narrower as the first and second element isolation films 110 and 120 move downwardly. In one example, an upper surface of the first element isolation film 110 may be disposed on a lower level than an upper surface of the second element isolation film 120. In one example, the upper surface of the first element isolation film 110 may be coplanar with the upper surface of the substrate 101, and an upper surface of the second element isolation film 120 may be disposed on a higher level than the upper surface of the substrate 101. However, the present disclosure is not limited thereto, and the upper surface of the second element isolation film 120 may be coplanar with the upper surface of the substrate 101.

In one example, the first and second element isolation films 110 and 120 may be formed of an insulating material. For example, the first and second element isolation films 110 and 120 may be an oxide, a nitride, or combinations thereof. In one example, the first element isolation film 110 may include a first insulating material, and the second element isolation film 120 may include a second insulating material different from the first insulating material. For example, the first element isolation film 110 may include silicon oxide, and the second element isolation film 120 may include silicon nitride.

The first gate structures GS1 may be disposed on the first region R1, and the second gate structures GS2 spaced apart from the first gate structures GS1 in the second direction (Y-direction) may be disposed on the second region R2.

The first gate structures GS1 may include first gate electrodes 160a and second gate electrodes 160b spaced apart from the first gate electrodes 160a in the second direction (Y-direction). In one example, each of the first gate electrodes 160a and the second gate electrodes 160b may extend in the second direction (Y-direction) and may be spaced apart from each other in the first direction (X-direction).

The second gate structure GS2 may be spaced apart from the first gate structures GS1 in the second direction (Y-direction). The second gate structure GS2 may include third gate electrodes 160c and the fourth gate electrodes 160d spaced apart from the third gate electrodes 160c in the second direction (Y-direction). In one example, each of the third gate electrodes 160c and the fourth gate electrodes 160d may extend in the second direction (Y-direction) and may be spaced apart from each other in the first direction (X-direction).

In an example implementation, each of the first to fourth gate electrodes 160a to 160d may include a 1-1 gate electrode 161a, a 1-2 gate electrode 162b, a 1-3 gate electrode 163c, and a 1-4 gate electrode 164d, which are spaced apart from each other in the first direction (X-direction). In this specification, a cross-sectional view of each of the first to fourth gate electrodes 160a to 160d in the first direction (X-direction) will be described based on the 1-1 to 1-4 gate electrodes 161a, 162b, 163c and 164d of the first gate electrode 160a. The first gate separation structure 115 may be disposed between the first region R1 and the second region R2 and may extend in the first direction (X-direction). The first gate separation structure 115 may separate the first and second gate structures GS1 and GS2 and the source/drain electrode structures 150 disposed on one side of the first and second gate structures GS1 and GS2. In one example, the first gate separation structure 115 may separate the second gate electrode 160b adjacent to a second region R2 of the first gate structures GS1 and the third gate electrode 160c adjacent to a first region R1 of the second gate structures GS2. In one example, the first gate separation structure 115 may separate the source/drain electrode structure 150 disposed on one side of the second gate electrode 160b and the source/drain electrode structure 150 disposed on one side of the third gate electrode 160c. The first gate separation structure 115 may be disposed on the first element isolation film 110, and a lower surface of the first gate separation structure 115 may be disposed within the first element isolation film 110. In one example, the first gate separation structure 115 may include at least one of an insulating material, for example, silicon oxide, silicon nitride, silicon oxynitride, or combinations thereof, but the present disclosure is not limited thereto.

Each of the second gate separation structures 125 may be disposed between the first gate structures GS1 and between the second gate structures GS2 and may extend in the first direction (X-direction). In one example, the second gate separation structure 125 disposed in the first region R1 may be disposed between the first gate electrode 160a and the second gate electrode 160b to separate the first gate electrode 160a and the second gate electrode 160b, and may separate the source/drain electrode structures 150 arranged in the first region R1. The second gate separation structure 125 disposed in the second region R2 may be disposed between the third gate electrode 160c and the fourth gate electrode 160d to separate the third gate electrode 160c and the fourth gate electrode 160d, and may separate the source/drain electrode structures 150 disposed in the second region R2. The second gate separation structure 125 may be disposed on the second element isolation film 120, and a lower surface of the second gate separation structure 125 may be disposed in the second element isolation film 120. In one example, the second gate separation structure 125 may include at least one of an insulating material, for example, silicon oxide, silicon nitride, silicon oxynitride, or combinations thereof, but the present disclosure is not limited thereto. In one example, the second gate separation structure 125 may include the same insulating material as the first gate separation structure 115.

Each of the first to fourth gate electrodes 160a to 160d may include electrodes 165 and gate dielectric liners 163 disposed between the electrodes 165 and the channel layer 140. In one example, the electrodes 165 included in each of the first to fourth gate electrodes 160a to 160d may include a first electrode 165a and a second electrode 165b meshed with the first electrode 165a. In one example, the channel layer 140 may be disposed between the first electrode 165a and the second electrode 165b. Each of the gate dielectric liners 163 may be disposed between the first and second electrodes 165a and the channel layers 140 and between the second electrode 165b and the channel layers 140.

The first gate electrode 160a and the second gate electrode 160b of the first gate structure GS1 may have a symmetrical structure with respect to the second gate separation structure 125 on the first region R1. The second electrode 165b of the first gate electrode 160a and the second electrode 165b of the second gate electrode 160b may be separated by the second gate separation structure 125 on the first region R1. In one example, the second electrode 165b of the first gate electrode 160a and the second electrode 165b of the second gate electrode 160b may be in contact with a side surface of the second gate separation structure 125 on the first region R1.

The third gate electrode 160c and the fourth gate electrode 160d of the second gate structure GS2 may have a symmetrical structure with respect to the second gate separation structure 125 on the second region R2. The second electrode 165b of the third gate electrode 160c and the second electrode 165b of the fourth gate electrode 160d may be separated by the second gate separation structure 125 on the second region R2. In one example, the second electrode 165b of the third gate electrode 160c and the second electrode 165b of the fourth gate electrode 160d may be in contact with a side surface of the second gate separation structure 125 of the second region R2.

The electrodes 165 may include a conductive material, and may include, for example, a metal nitride such as titanium nitride (TiN), tantalum nitride (TaN), or tungsten nitride (WN), and/or a metallic material such as aluminum (Al), tungsten (W), or molybdenum (Mo), or a semiconductor material such as doped polysilicon. According to example implementations, the electrodes 165 may be comprised of two or more multilayer structures. In an example implementation, the first electrode 165a may include a first conductive material, and the second electrode 165b may include a second conductive material different from the first conductive material. However, the present disclosure is not limited thereto, and the first and second electrodes 165a and 165b may include the same conductive material.

In an example implementation, the first gate separation structure 115 may penetrate through the second gate electrode 160b, the third gate electrode 160c, the gate dielectric liners 163 on the first element isolation film 110, and the channel layers 140 in a vertical direction (Z-direction). In one example, the first electrode 165a of the second gate electrode 160b and the first electrode 165a of the third gate electrode 160c may be separated by the first gate separation structure 115. The first electrode 165a of the second gate electrode 160b and the first electrode 165a of the third gate electrode 160c may be in contact with a side surface of the first gate separation structure 115.

Since the first gate structure GS1 may have the same structure as the second gate structure GS2, descriptions thereof will be based on the first gate structure GS1. The descriptions related to the first gate structure GS1 may also be applied to the second gate structure GS2.

Referring to FIG. 3A, the first electrode 165a may include a first portion 165a_1 and first protrusion portions 165a_2 extending from the first portion 165a_1 and protruding toward the second gate separation structure 125. The first protrusion portions 165a_2 may be spaced apart from each other in the vertical direction (Z-direction). The second electrode 165b may include a second portion 165b_1 and second protrusion portions 165b_2 extending from the second portion 165b_1 and alternately disposed with the first protrusion portions 165a_2 in the vertical direction (Z-direction). The second protrusion portions 165b_2 may alternately disposed with the first protrusion portions 165a_2 in the vertical direction (Z-direction) and may be spaced apart from each other in the vertical direction (Z-direction).

A first thickness Ta of the first protrusion portion 165a_2 of the first electrode 165a in the vertical direction (Z-direction) may be smaller than a second thickness Tb of the second protrusion portion 165b_2 of the second electrode 165b in the vertical direction (Z-direction). However, the present disclosure is not limited thereto, and the first thickness Ta of the first protrusion portion 165a_2 may be substantially the same as the second thickness Tb of the second protrusion portion 165b_2.

The second electrode 165b may be in contact with the insulating pattern 105 on the substrate 101. A side surface of the insulating pattern 105 may be in contact with the second portion 165b_1 of the second electrode 165b, and an upper surface of the insulating pattern 105 may be in contact with the second protrusion portion 165b_2 disposed on a lowermost end, among the second protrusion portions 165b_2 of the second electrode 165b.

The channel layers 140 on the first region R1 may be disposed between the first electrode 165a and the second electrode 165b of the first gate electrode 160a and between the first electrode 165a and the second electrode 165b of the second gate electrode 160b. The channel layers 140 disposed on the first region R1 may be referred to as a ‘first channel layer 140a.’

The channel layers 140 on the second region R2 may be disposed between the first electrode 165a and the second electrode 165b of the third gate electrode 160c and between the first electrode 165a and the second electrode 165b of the fourth gate electrode 160d. The channel layers 140 disposed on the second region R2 may be referred to as a ‘second channel layer 140b.’

In the cross-sectional view in the second direction (Y-direction), the channel layer 140 may be disposed to extend between the first protrusion portion 165a_2 and the second portion 165b_1, between the first protrusion portion 165a_2 and the second protrusion portion 165b_2, between the first portion 165a_1 and the second protrusion portion 165b_2, and between the first protrusion portion 165a_2 and the second protrusion portion 165b_2. For example, the channel layer 140 may be formed according to a surface profile between the first electrode 165a and the second electrode 165b. The channel layer 140 may extend between the first electrode 165a and the second electrode 165b, between the first portion 165a_1 of the first electrode 165a and the insulating pattern 105, and between the first portion 165a_1 of the first electrode 165a and the first element isolation film 110. In one example, each of the first gate structure GS1 and the second gate structure GS2 may be around a periphery of the channel layers 140.

The channel layer 140 may include a two-dimensional material. In one example, the channel layer 140 may include a transition metal dichalcogenide (TMD) material. The transition metal dichalcogenide material is a two-dimensional material having semiconductor properties and is a compound of a transition metal and a chalcogen element. The transition metal may include, for example, at least one of Mo, W, Nb, V, Ta, Ti, Zr, Hf, Co, Tc or Re, and the chalcogen element may include, for example, at least one of S, Se, or Te. As a specific example, the TMD may include MoS₂, MoSe₂, MoTe₂, WS₂, WSe₂, WTe₂, ZrS₂, ZrSe₂, HfS₂, HfSe₂, NbSe₂, and ReSe₂. However, the present disclosure is not limited thereto. In one example, the first channel layer 140a and the second channel layer 140b may include different two-dimensional materials. For example, the first channel layer 140a may include molybdenum diselenide (MoSe₂), and the second channel layer 140b may include tungsten diselenide (WSe₂).

The gate dielectric liner 163 may include a first gate dielectric liner 163a disposed between the first electrode 165a and the channel layer 140, and a second gate dielectric liner 163b disposed between the second electrode 165b and the channel layer 140. In one example, the first gate dielectric liner 163a may be in contact with the first electrode 165a and the channel layer 140, and the second gate dielectric liner 163b may be in contact with the second electrode 165b and the channel layer 140. In one example, the channel layer 140 may extend between the first gate dielectric liner 163a and the second gate dielectric liner 163b. In one example, the second gate dielectric liner 163b may extend between the second electrode 165b and the channel layer 140, between the insulating pattern 105 and the channel layer 140, and between the first element isolation film 110 and the channel layer 140.

The gate dielectric liner 163 may include an oxide, a nitride, or a high-κ material. The high-κ material may refer to a dielectric material having a higher dielectric constant than a silicon oxide (SiO₂) film. The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

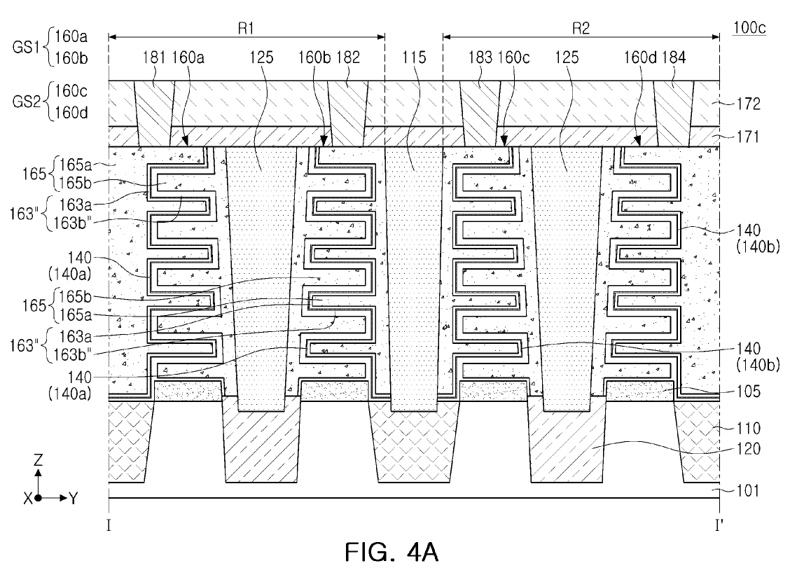

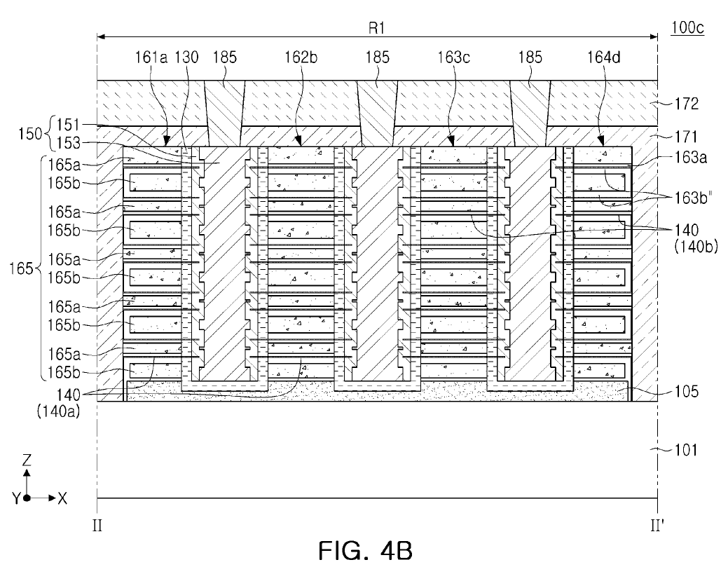

A thickness T1 of the first gate dielectric liner 163a may be substantially the same as a thickness of the second gate dielectric liner 163b. However, the present disclosure is not limited thereto, and the thickness T1 of the first gate dielectric liner 163a may be different from a thickness of the second gate dielectric liner 163b. In one example, the thickness of the second gate dielectric liner 163b may be greater than the thickness T1 of the first gate dielectric liner 163a. An example implementation related thereto will be described with reference to FIGS. 4A and 4B.

The thickness T1 of each of the first and second gate dielectric liners 163a and 163b may be greater than a thickness T2 of the channel layer 140. In one example, the channel layer 140 may include a monolayer of the transition metal chalcogenide material, and the channel layer 140 may have an atomic level thickness. In one example, the thickness T2 of the channel layer 140 may be about 1 nm or less, for example, about 0.65 nm to about 0.7 nm. In one example, the thickness of each of the first and second gate dielectric liners 163a and 163b may be about 2.0 nm to about 2.4 nm.

The source/drain electrode structure 150 may be disposed on at least one side of each of the first to fourth gate electrodes 160a to 160d. In one example, each of the source/drain electrode structures 150 may be disposed between the 1-1 to 1-4 gate electrodes 161a, 162b, 163c and 164d. For example, the source/drain electrode structures 150 may be disposed between the 1-1 gate electrode 161a and the 1-2 gate electrode 162b, between the 1-2 gate electrode 162b and the 1-3 gate electrode 163c, and between the 1-3 gate electrode 163c and the 1-4 gate electrode 164d. The source/drain electrode structures 150 may be spaced apart from each other in the first direction (X-direction) and the second direction (Y-direction).

The source/drain electrode structure 150 may include a first source/drain electrode layer 151 covering a side surface of the spacer layer 130 and the channel layer 140, and a second source/drain electrode layer 153 on a side surface of the first source/drain electrode layer 151. In one example, the first source/drain electrode layer 151 may be formed according to a surface profile of the channel layer 140 protruding through the side surface of the spacer layer 130 and the spacer layer 130 in the first direction (X-direction), and the second source/drain electrode layer 153 may be disposed on the first source/drain electrode layer 151. In one example, a thickness of the first source/drain electrode layer 151 in the first direction (X-direction) may be smaller than a thickness of the second source/drain electrode layer 153 in the first direction (X-direction).

In one example, the first source/drain electrode layer 151 may include a first metallic material, and the second source/drain electrode layer 153 may include a second metallic material different from the first metallic material. In one example, the first source/drain electrode layer 151 may include a metallic material for lowering contact resistance to the channel layer 140. For example, the first metallic material may include niobium (Nb), and the second metallic material may include a conductive material. For example, the second metallic material may include a metal nitride such as a titanium nitride (TiN), a tantalum nitride (TaN), or a tungsten nitride (WN), and/or a metallic material such as aluminum (Al), tungsten (W), or molybdenum (Mo). However, the present disclosure is not limited thereto, and in another example implementation, the first and second source/drain electrode layers 151 and 153 may include a semiconductor material such as doped polysilicon.

In this specification, the source/drain electrode structure 150 disposed in the first region R1 may be referred to as a ‘first source/drain electrode structure,’ and the source/drain electrode structure 150 disposed in the second region R2 may be referred to as a ‘second source/drain electrode structure.’

The insulating patterns 105 may extend in the first direction (X-direction) and may be spaced apart from each other in the second direction (Y-direction). A lower surface of the spacer layer 130 may be in contact with an upper surface of the insulating pattern 105. The upper surface of the insulating pattern 105 may include a first upper surface portion in contact with the second protrusion portion 165b_2 of the second electrode 165b and a second upper surface portion in contact with the spacer layer 130, and the second upper surface portion may be disposed on a lower level than the first upper surface portion. In one example, the insulating pattern 105 may include at least one of silicon oxide, silicon nitride, silicon oxynitride, or combinations thereof, but the present disclosure is not limited thereto.

The channel layer 140 may extend from between the first and second gate dielectric liners 163a and 163b and may penetrate through the spacer layer 130 and may thus be connected to the source/drain electrode structure 150. In one example, the channel layers 140 may penetrate through the spacer layers 130 in the first direction (X-direction) and may thus be in contact with the first source/drain electrode layer 151.

The spacer layers 130 may be disposed between the first to fourth gate electrodes 160a to 160d and the source/drain electrode structures 150. In one example, the spacer layer 130 may be disposed between a side surface of each of the first to fourth gate electrodes 160a to 160d and a side surface of the source/drain electrode structure 150. The spacer layers 130 may insulate the first to fourth gate electrodes 160a to 160d and the source/drain electrode structures 150. The spacer layers 130 may be formed of a single layer or a multilayer structure according to example implementations. The spacer layers 130 may be formed of at least one of an oxide, a nitride or an oxynitride, and may be formed of a low-κ film. The spacer layers 130 may include, for example, at least one of SiO, SiN, SiCN, SiOC, SiON or SiOCN. In one example, the spacer layer 130 may include the same material as the insulating pattern 105, and in this case, an interface between the spacer layer 130 and the insulating pattern 105 may not be distinguished.

In an example implementation, the semiconductor device 100 may further include a first interlayer insulating layer 171 disposed on the first to fourth gate electrodes 160a to 160d, a second interlayer insulating layer 172 on the first interlayer insulating layer 171, first to fourth gate contacts 181 to 184 connected to the first to fourth gate electrodes 160a to 160d, and source/drain contacts 185 connected to the source/drain electrode structures 150.

The first interlayer insulating layer 171 may be disposed to cover the first and second gate structures GS1 and GS2. The first interlayer insulating layer 171 may cover upper surfaces of the first and second gate structures GS1 and GS2 and side surfaces of the first and second gate structures GS1 and GS2 adjacent to an edge of the substrate 101.

The 1-1 gate electrode 161a and the 1-4 gate electrode 164d may be disposed on an outermost position in the first direction (X-direction), among the first to fourth gate electrodes 160a to 160d, and a portion of the channel layer 140 disposed between the first electrode 165a and the second electrode 165b of each of the 1-1 gate electrode 161a and the 1-4 gate electrode 164d may be exposed from a space between the first and second gate dielectric liners 163a and 163b and may be disposed between the first interlayer insulating layer 171 and the second gate dielectric liner 163b.

The second interlayer insulating layer 172 may be disposed to cover an upper surface of the first interlayer insulating layer 171. In one example, the first and second interlayer insulating layers 171 and 172 may include at least one of an oxide, a nitride, and an oxynitride, and may include, for example, a low-κ material.

The first to fourth gate contacts 181 to 184 may penetrate through the first interlayer insulating layer 171 and the second interlayer insulating layer 172 and may be connected to the first and second gate structures GS1 and GS2. In one example, the first gate contact 181 may be in contact with an upper surface of the first gate electrode 160a, the second gate contact 182 may be in contact with the upper surface of the second gate electrode 160b, the third gate contact 183 may be in contact with the upper surface of the third gate electrode 160c, and the fourth gate contact 184 may be in contact with the upper surface of the fourth gate electrode 160d.

The source/drain contacts 185 may be connected to the source/drain electrode structures 150 by penetrating through the first interlayer insulating layer 171 and the second interlayer insulating layer 172.

Upper surfaces of the first to fourth gate contacts 181 to 184 and upper surfaces of the source/drain contacts 185 may be coplanar with an upper surface of the second interlayer insulating layer 172.

The first to fourth gate contacts 181 to 184 and the source/drain contact 185 may include a metallic material such as aluminum (Al), tungsten (W), or molybdenum (Mo). The first to fourth gate contacts 181 to 184 and the source/drain contacts 185 may further include a barrier material film, such as a titanium nitride (TiN), a tantalum nitride (TaN), or a tungsten nitride (WN) film, which surrounds the metallic material.

The semiconductor device 100 according to example implementations of the present disclosure may include a channel layer 140 which is a two-dimensional material, and may thus provide the semiconductor device 100 having improved integration, and the semiconductor device 100 may include electrodes 165 including the first electrode 165a disposed on one surface of the channel layer 140 and the second electrode 165b disposed on the other surface corresponding to one surface of the channel layer 140, thereby securing an effective cross-sectional area of the channel layer 140. Accordingly, the semiconductor device 100 having improved electrical characteristics may be provided.

FIGS. 3B and 3C are enlarged views of another example implementation of region A of the semiconductor device of FIG. 2A.

Referring to FIG. 3B, a semiconductor device 100a may include a channel layer 140’, and the remaining components except for the channel layer 140’ may be identical to or may correspond to the components illustrated in FIG. 3A. The channel layer 140’ may include a plurality of two-dimensional material layers (multilayer structures). In one example, the channel layer 140’ may include a first channel layer 141 and a second channel layer 142 on the first channel layer 141. Each of the first channel layer 141 and the second channel layer 142 may include a single layer of a transition metal chalcogenide material. In one example, a thickness T2’ of the channel layer 140’ may be the sum of a thickness of the first channel layer 141 and a thickness of the second channel layer 142. In one example, a thickness T1’ of each of the first and second gate dielectric liners 163a and 163b may be greater than the thickness T2’ of the channel layer 140’. For example, when each of the first channel layer 141 and the second channel layer 142 is molybdenum diselenide (MoSe₂) or tungsten diselenide (WSe₂), the thickness T2’ of the channel layer 140’ may be about 1.3 nm to about 1.4 nm.

Referring to FIG. 3C, a semiconductor device 100b may include gate dielectric liners 163’, and the remaining components except for the gate dielectric liners 163’ may be identical to or may correspond to the components illustrated in FIGS. 3A or 3B. The gate dielectric liners 163’ may include a first gate dielectric liner 163a’ disposed between the first electrode 165a and the channel layer 140, and a second gate dielectric liner 163b’ disposed between the second electrode 165b and the channel layer 140.

The first gate dielectric liner 163a’ may include a 1-1 gate dielectric liner 1631a and a 1-2 gate dielectric liner 1632a on the 1-1 gate dielectric liner 1631a. The second gate dielectric liner 163b’ may include a 2-1 gate dielectric liner 1631b and a 2-2 gate dielectric liner 1632b on the 2-1 gate dielectric liner 1631b.

The channel layer 140 may be in contact with the 1-1 gate dielectric liner 1631a and the 2-2 gate dielectric liner 1632b.

The 1-1 gate dielectric liner 1631a and the 2-1 gate dielectric liner 1631b may include a first dielectric material, and the 1-2 gate dielectric liner 1632a and the 2-2 gate dielectric liner 1632b may include a second dielectric material having a higher dielectric constant than the first dielectric material. In one example, the 1-1 gate dielectric liner 1631a and the 2-1 gate dielectric liner 1631b may include silicon oxide, and the 1-2 gate dielectric liner 1632a and the 2-2 gate dielectric liner 1632b may include a high-κ material. The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The channel layer 140 may be formed by growing by using the 2-2 gate dielectric liner 1632b of the second gate dielectric liner 163b’ as a seed layer.

FIG. 4A is a cross-sectional view illustrating taken along line I-I’ of the semiconductor device illustrated in FIG. 1 according to another example implementation. FIG. 4B is a cross-sectional view illustrating taken along line II-II’ of the semiconductor device illustrated in FIG. 1 according to another example implementation.

Referring to FIGS. 4A and 4B, a semiconductor device 100c may include a gate dielectric liner 163”, and the remaining components except for the gate dielectric liner 163” may be identical to or may correspond to the components illustrated in FIGS. 2A and 2B. The gate dielectric liner 163” may include a first gate dielectric liner 163a disposed between the first electrode 165a and the channel layer 140, and a second gate dielectric liner 163b” disposed between the second electrode 165b and the channel layer 140. In one example, the second gate dielectric liner 163b” may extend from a space between the second electrode 165b and the channel layer 140 to a space between the first element isolation film 110 and the channel layer 140 and a space between the insulating pattern 105 and the second electrode 165b. For example, the second gate dielectric liner 163b” may include a first liner portion disposed between the second electrode 165b and the channel layer 140, and second liner portions extending from the first liner portion and disposed between the insulating pattern 105 and the channel layer 140, between the first element isolation film 110 and the channel layer 140, and between the insulating pattern 105 and the second electrode 165b.

A thickness of the first liner portion of the second gate dielectric liner 163b” disposed between the second electrode 165b and the channel layer 140 may be greater than a thickness of the first gate dielectric liner 163a. In one example, a thickness of the second liner portion of the second gate dielectric liner 163b”, which extends from the first liner portion and is disposed between the insulating pattern 105 and the channel layer 140 and between the first element isolation film 110 and the channel layer 140, may be substantially the same as the thickness of the first gate dielectric liner 163a.

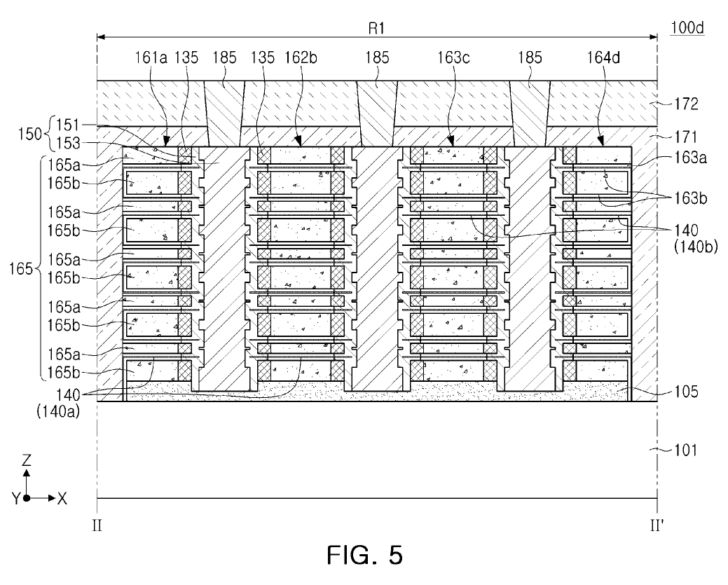

FIG. 5 is a cross-sectional view taken along line II-II’ of the semiconductor device illustrated in FIG. 1 according to another example implementation.

Referring to FIG. 5, a semiconductor device 100d may include spacer patterns 135 disposed between the first electrode 165a and the source/drain electrode structure 150 and between the second electrode 165b and the source/drain electrode structure 150. The remaining components except for the spacer patterns 135 may be identical to or may correspond to the components illustrated in FIGS. 2A and 2B. In one example, the spacer patterns 135 may be oxidation patterns formed by an oxidation process on a side surface of the first protrusion portion (e.g., the first protrusion portion 165a_2 of FIG. 3A) of the first electrode 165a and a side surface of the second protrusion portion (e.g., the second protrusion portion 165b_2 of FIG. 3A) of the second electrode 165b. In one example, the spacer patterns 135 disposed on side surfaces of the first and second electrodes 165a and 165b spaced apart from each other in the vertical direction (Z-direction) may be spaced apart from each other in the vertical direction (Z-direction).

The channel layer 140 may protrude between the spacer patterns 135 spaced apart from each other in the vertical direction (Z-direction) and may be connected to the source/drain electrode structure 150. In one example, the first source/drain electrode layer 151 may cover a space between the spacer patterns 135 spaced apart from each other in the vertical direction (Z-direction), and the channel layer 140.

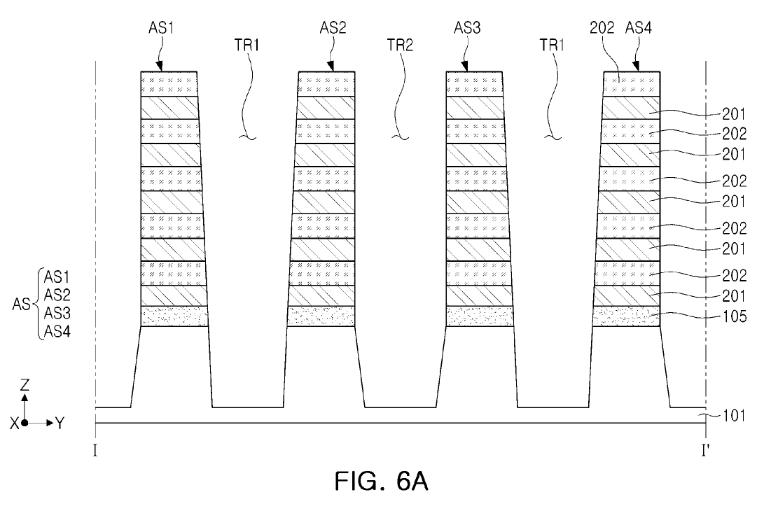

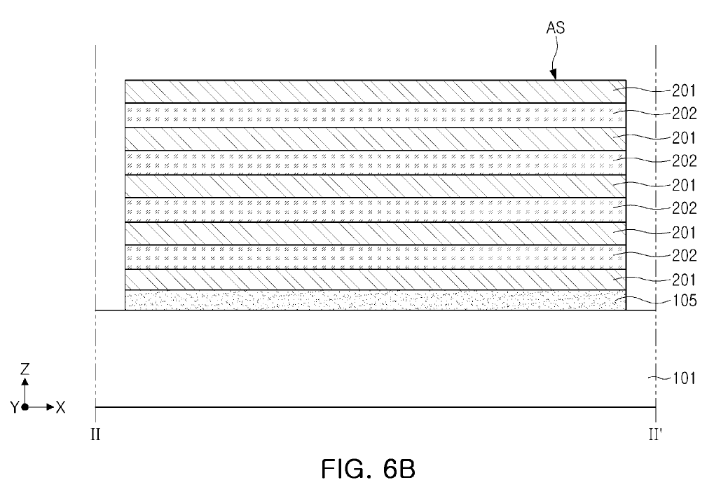

FIGS. 6A-18B are views illustrating a method of manufacturing a semiconductor device according to an example implementation of the present disclosure according to the process sequence. FIGS. 6A, 7, 8A, 9A, 10A, 11, 12A, 13A and 14 illustrate cross-sections taken along the cutting line I-I' of FIG. 1, FIGS. 6B, 8B, 9B, 10B, 12B, 13B, 15, 16A, 17 and 18A illustrate cross-sections taken along the cutting line II-II' of FIGS. 1, and 16B and 18B illustrate cross-sections taken along the cutting line III-III' of FIG. 1.

Referring to FIGS. 6A and 6B, stack structure AS (AS1 to AS4) may be formed on a substrate 101 in which first sacrificial layers 201 and second sacrificial layers 202 are alternately stacked in the vertical direction (Z-direction). An etching process may be performed on the stack structure AS and an upper portion of the substrate 101 to form first and second trenches TR1 and TR2 spaced apart from each other in the second direction (Y-direction) and extending in a first direction (X-direction). The first trench TR1 may define a position in which a second element isolation film 120 described below is formed, and the second trench TR2 may define a position in which a first element isolation film 110 described below is formed.

The second sacrificial layer 202 may have an etching selectivity with respect to the substrate 101 and the first sacrificial layer 201. In one example, the first sacrificial layer 201 may include silicon (Si), and the second sacrificial layer 202 may include silicon germanium (SiGe). In one example, the insulating pattern 105 may be formed between the substrate 101 and a first sacrificial layer 201 in a lowermost end. The insulating pattern 105 may include at least one of silicon oxide, silicon nitride, silicon oxynitride, or combinations thereof, but the present disclosure is not limited thereto.

The first and second trenches TR1 and TR2 may be formed by etching the stack structure AS and an upper portion of the substrate 101.

The stack structure AS may include first to fourth stack structures AS1 to AS4 spaced apart from each other in the second direction (Y-direction) and extending in the first direction (X-direction). The first and second stack structures AS1 and AS2 and the third and fourth stack structures AS3 and AS4 may formed to be spaced apart from each other in the second direction (Y-direction) by the first trench TR1, and the second and third stack structures AS2 and AS3 may be formed to spaced apart from each other in the second direction (Y-direction) by the second trench TR2.

The first region R1 and the second region R2 of the substrate 101 of FIG. 1 may be defined by the second trench TR2, and positions in which the first gate structure GS1 and the second gate structure GS2 of FIG. 1 are formed may be defined by the first trenches TR1. The first and second trenches TR1 and TR2 may be spaced apart from each other in the second direction (Y-direction) and may extend in the first direction (X-direction), and the first trenches TR1 may be spaced apart from each other in the second direction (Y-direction) with the second trench TR2 interposed therebetween.

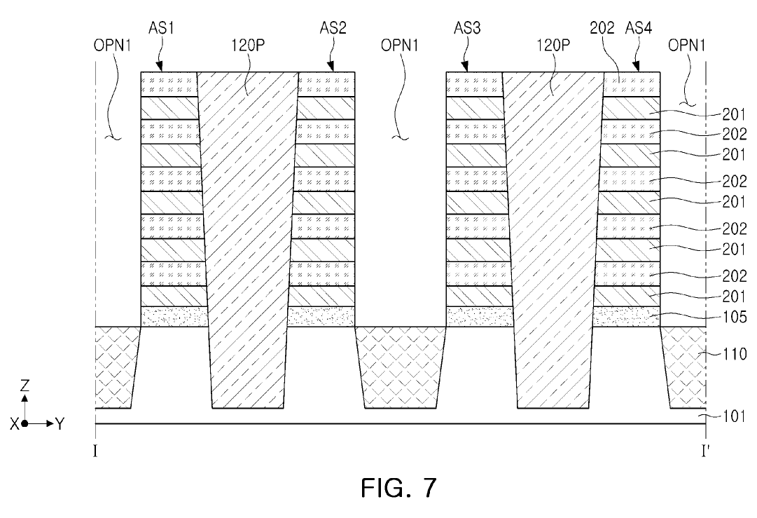

Referring to FIG. 7, a first element isolation film 110 may be formed in the substrate 101 exposed through the second trench TR2, and a second element isolation structure 120P may be formed in the first trench TR1.

The first element isolation film 110 may be formed by filling a first insulating material in the second trench TR2 to form the first element isolation structure, and then performing an etching process on the first element isolation structure. The first insulating material may be removed so that side surfaces of the first and second sacrificial layers 201 and 202 are exposed, and thus, a first opening OPN1 exposing side surfaces of the first and second sacrificial layers 201 and 202 may be formed. The first element isolation film 110 may be formed to be coplanar with the upper surface of the substrate 101.

The second element isolation structure 120P may be formed by filling the first trenches TR1 with a second insulating material different from the first insulating material. The second element isolation structures 120P may be coplanar with upper surfaces of the first to fourth sacrificial structures AS1 to AS4. The second insulating material may be an insulating material having an etching selectivity with respect to the first insulating material. For example, the first insulating material may include silicon oxide, and the second insulating material may include silicon nitride. In this specification, the second element isolation structure 120P may be referred to as a ‘first sacrificial structure.’

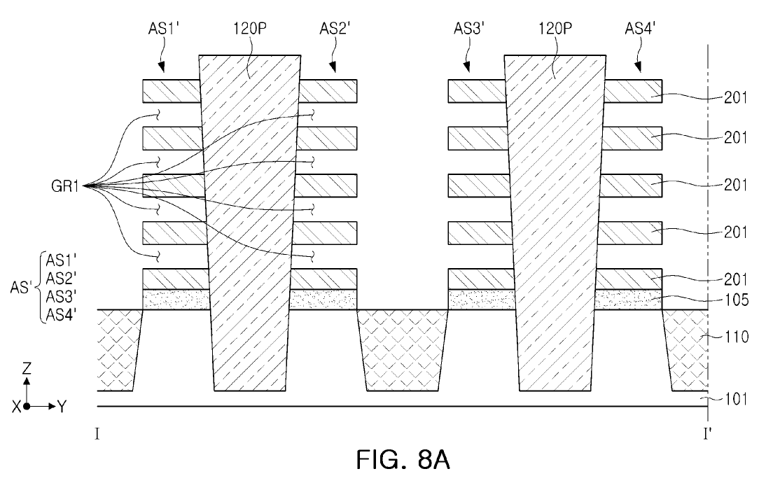

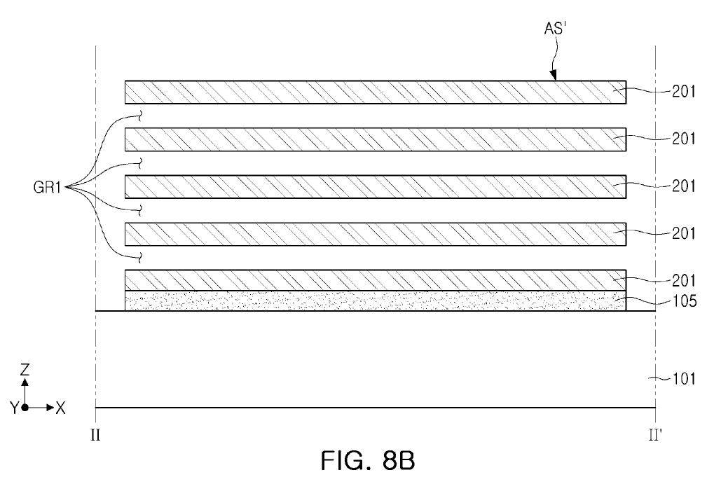

Referring to FIGS. 6A, 6B, 8A and 8B, the second sacrificial layers 202 may be removed from the stack structures AS (AS1 to AS4) to form sacrificial structures AS’ (AS1’ to AS4’) in which first gap regions GR1 are formed between the first sacrificial layers 201.

The second sacrificial layers 202 may be selectively removed with respect to the first sacrificial layers 201 by performing a wet etching process. As the second sacrificial layers 202 are removed, upper and lower surfaces of the first sacrificial layers 201 and side surfaces of the second element isolation structure 120P may be exposed.

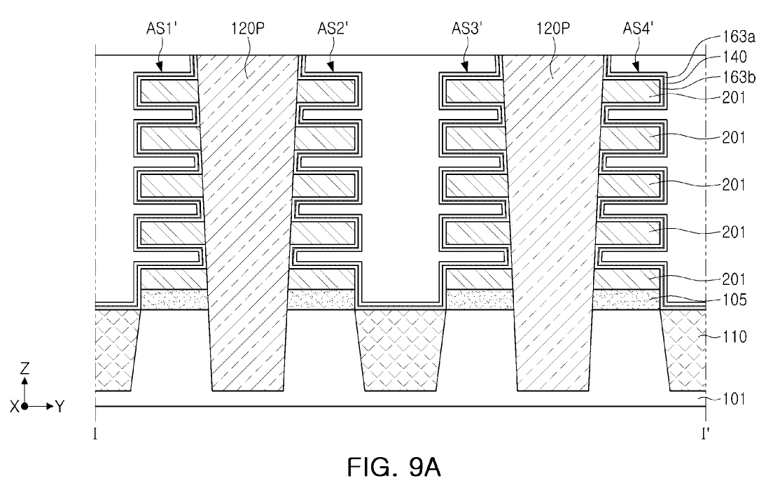

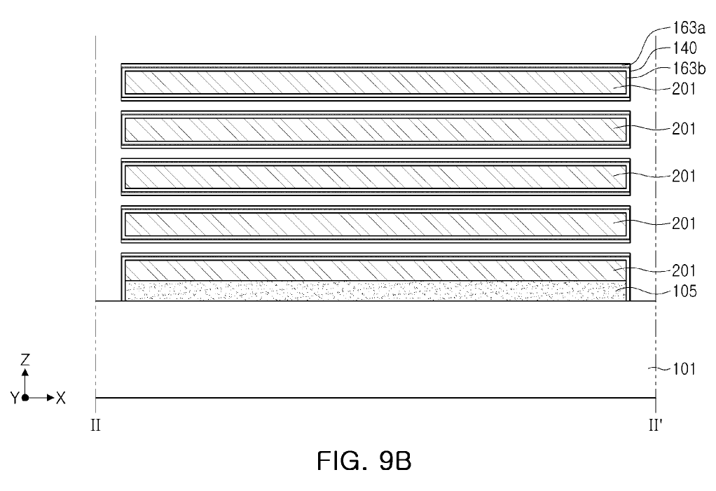

Referring to FIGS. 9A and 9B, a second gate dielectric liner 163b, a channel layer 140, and a first gate dielectric liner 163a may be sequentially formed within the first gap regions GR1. The second gate dielectric liner 163b may be conformally formed according to a side surface of the second element isolation structure 120P exposed through the first gap regions GR1 and a surface profile of the first sacrificial layers 201. The second gate dielectric liner 163b may extend from a surface of the first sacrificial layers 201 to the side surface of the insulating pattern 105 and the upper surface of the first element isolation film 110. The channel layer 140 may be formed by growing on the second gate dielectric liner 163b using the second gate dielectric liner 163b as a seed layer.

A process of forming the second gate dielectric liner 163b may include an operation of forming a 2-1 gate dielectric liner (e.g., the 2-1 gate dielectric liner 1631b of FIG. 3C) on the side surface of the second element isolation structure 120P and the surface of the first sacrificial layers 201, and an operation of forming a 2-2 gate dielectric liner (e.g., the 2-2 gate dielectric liner 1632b of FIG. 3C) including a high-κ material on the 2-1 gate dielectric liner. The channel layer 140 may be grown on the 2-2 gate dielectric liner 1632b.

The channel layer 140 formed on the second gate dielectric liner 163b may be a two-dimensional material layer of a monolayer. However, the present disclosure is not limited thereto, and the channel layer 140 may be a plurality of two-dimensional material layers. The two-dimensional material may be, for example, a transition metal chalcogenide material. In one example, a first channel layer (e.g., the first channel layer 140a of FIG. 2A) may be formed on side profiles of the first and second sacrificial structures AS1’ and AS2’ and the second element isolation structure 120P, and a second channel layer (e.g., the second channel layer 140b of FIG. 2A) different from the first channel layer may be formed on side profiles of the third and fourth sacrificial structures AS3’ and AS4’ and the second element isolation structure 120P.

The first gate dielectric liner 163a may be conformally formed on the channel layer 140 formed within the first gap regions GR1. The first gate dielectric liner 163a may be formed in the same process as the second gate dielectric liner 163b. Referring to FIG. 9B, which is a cross-sectional view in the first direction (X-direction), the channel layer 140 formed on side surfaces of the first sacrificial layers 201 on the upper surface of the substrate 101 and the side surface of the insulating pattern 105 may be exposed.

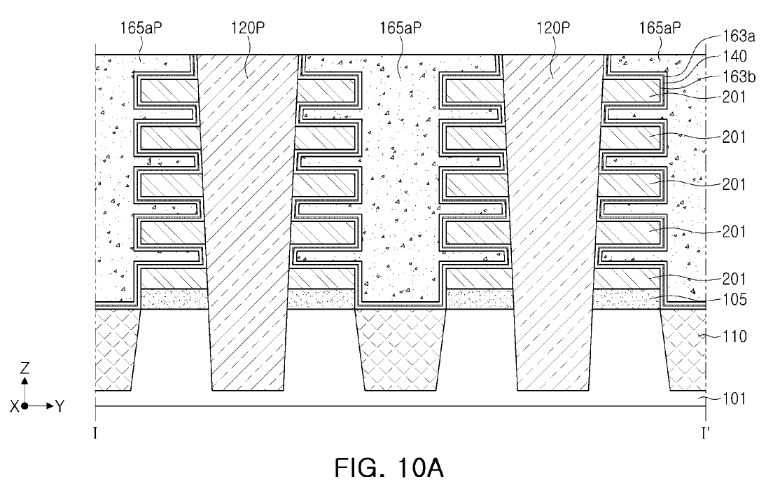

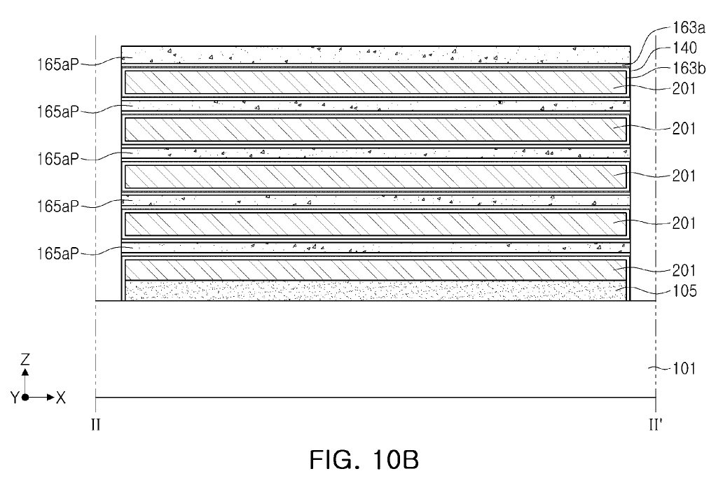

Referring to FIGS. 10A and 10B, a first electrode structure 165aP may be formed on the first gate dielectric liner 163a. The first electrode structure 165aP may include a first conductive material. The first conductive material may include, for example, a metal nitride such as a titanium nitride (TiN), a tantalum nitride (TaN) or a tungsten nitride (WN), and/or a metallic material such as aluminum (Al), tungsten (W), or molybdenum (Mo), or a semiconductor material such as doped polysilicon. In one example, the first electrode structure 165aP may fill upper regions of the first element isolation films 110 and the first gap regions GR1 of FIGS. 8A and 8B.

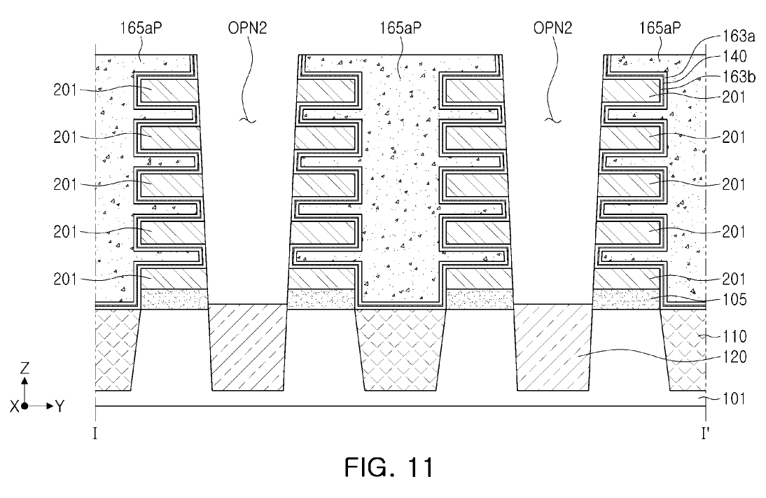

Referring to FIG. 11, a portion of the second element isolation structure 120P may be removed to form a second element isolation film 120. A portion of the second element isolation structure 120P may be removed to form a second opening OPN2, and the side surfaces of the first sacrificial layers 201, a side surface of the second gate dielectric liner 163b, and the side surface of the insulating pattern 105 may be exposed through the second opening OPN2. In one example, the upper surface of the second element isolation film 120 may be formed on a higher level than the upper surface of the first element isolation film 110 and a lower surface of the insulating pattern 105.

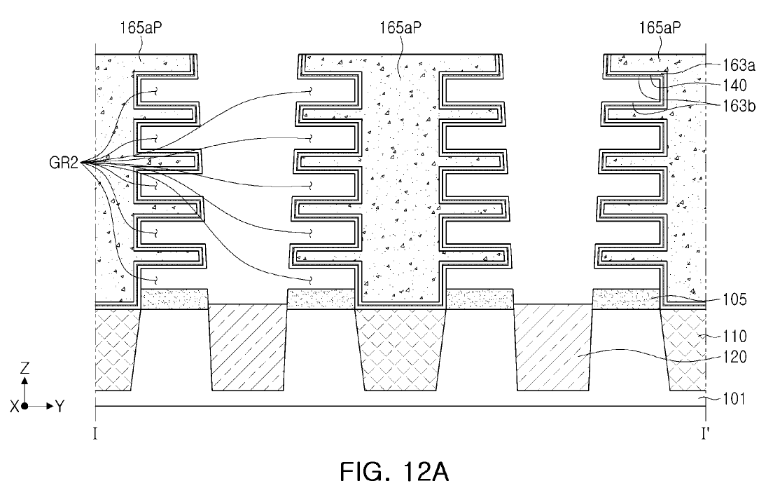

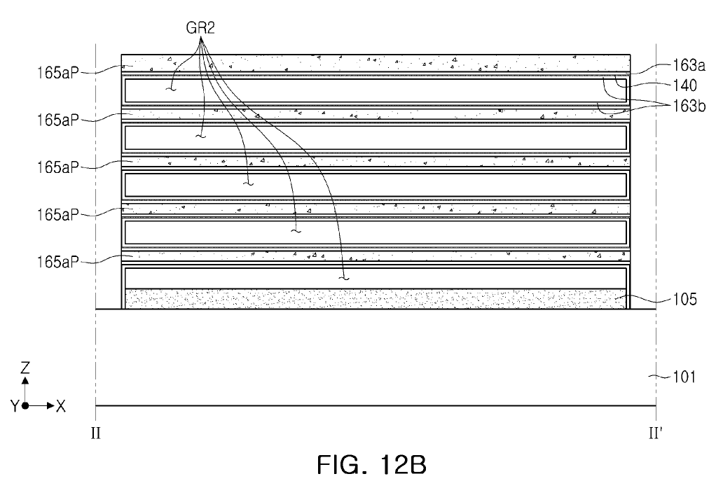

Referring to FIGS. 12A and 12B, the first sacrificial layers 201 may be removed to form second gap regions GR2. As the first sacrificial layers 201 are removed, upper surfaces of the second gate dielectric liner 163b and the insulating pattern 105 may be exposed.

In another example implementation, the first sacrificial layers 201 may be removed to additionally form a gate dielectric liner (not illustrated) on the exposed second gap regions GR2, and thus the second gate dielectric liner 163b” of FIG. 4A and FIG. 4B may be formed.

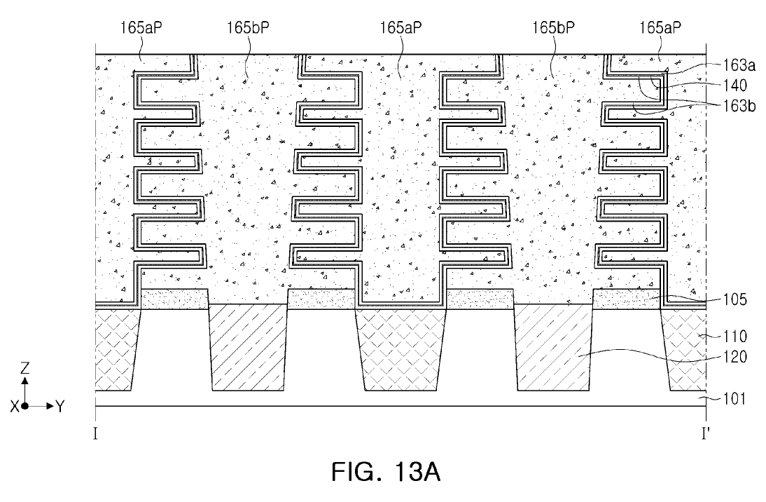

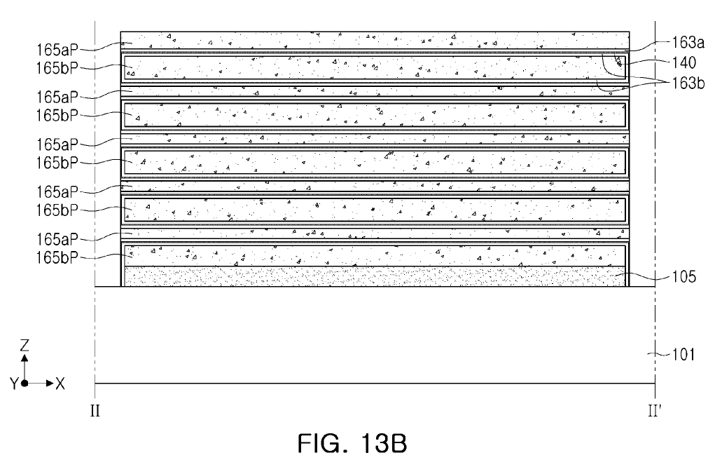

Referring to FIGS. 13A and 13B, a second electrode structure 165bP may be formed on an upper region of the second element isolation film 120, and filling the second gap regions GR2. The second electrode structure 165bP may include a second conductive material different from the first conductive material of the first electrode structure 165aP. However, the present disclosure is not limited thereto, and the second electrode structure 165bP may include the same conductive material as the first conductive material of the first electrode structure 165aP.

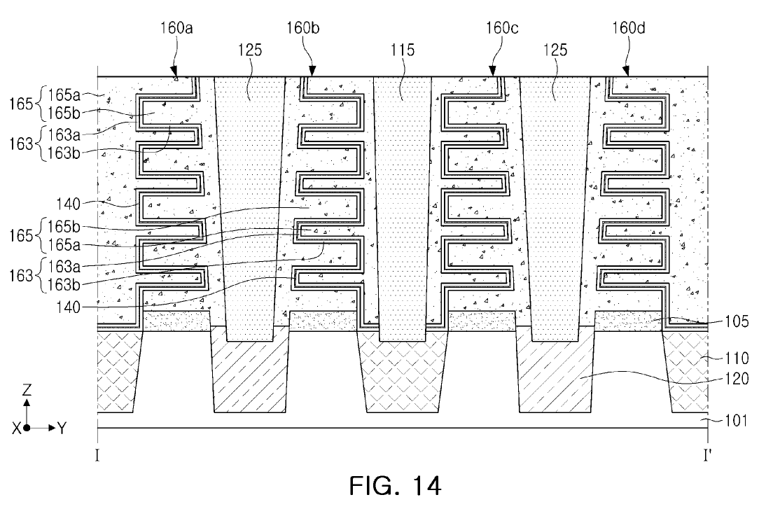

Referring to FIG. 14, a first gate separation structure 115 penetrating through the first electrode structure 165aP in the vertical direction (Z-direction) on the first element isolation film 110, and a second gate separation structure 125 penetrating through the second electrode structure 165bP in the vertical direction (Z-direction) on the second element isolation film 120 may be formed. As the first gate separation structure 115 is formed, the first and second gate structures GS1 and GS2 of FIG. 1 may be defined, and as the second gate separation structure 125 is formed, the first and second gate electrodes 160a and 160b of the first gate structure GS1 and the third and fourth gate electrodes 160c and 160d of the second gate structure GS2 may be defined, respectively.

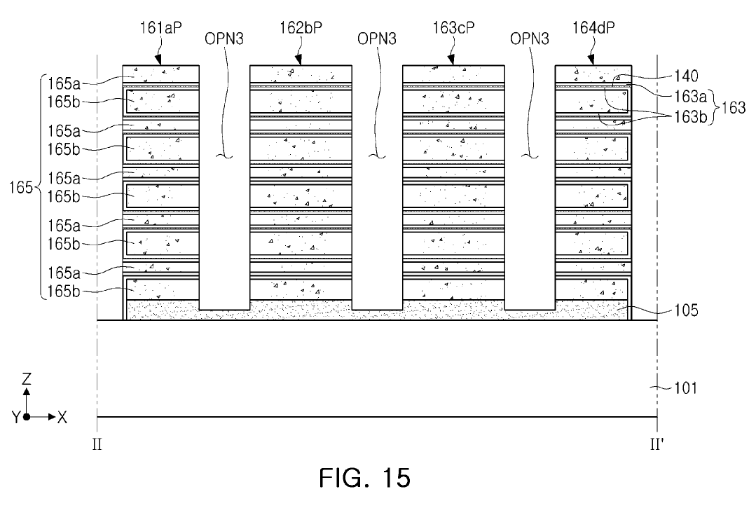

Referring to FIG. 15, third openings OPN3 extending in the second direction (Y-direction) by penetrating through each of the first to fourth gate electrodes 160a to 160d may be formed. By forming the third openings OPN3 spaced apart from each other in the first direction (X-direction) and extending in the second direction (Y-direction) for each of the first to fourth gate electrodes 160a to 160d, each of the first to fourth gate electrodes 160a to 160d may include a 1-1 gate electrode 161aP, a 1-2 gate electrode 162bP, a 1-3 gate electrode 163cP, and a 1-4 gate electrode 164dP spaced apart from each other in the first direction (X-direction).

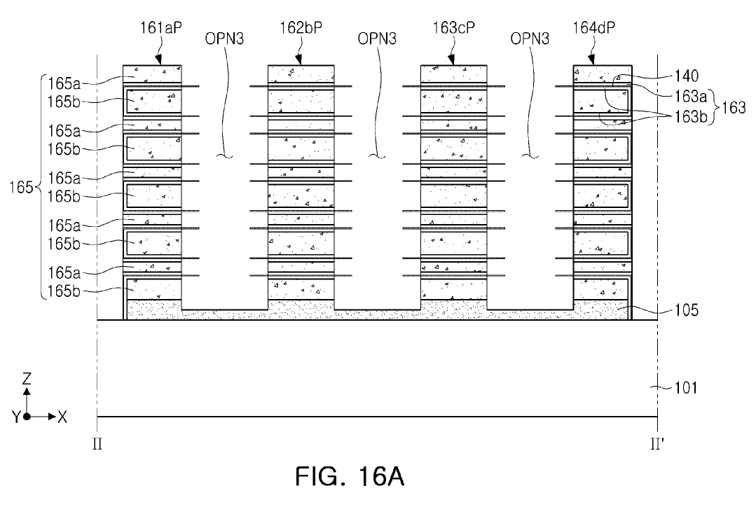

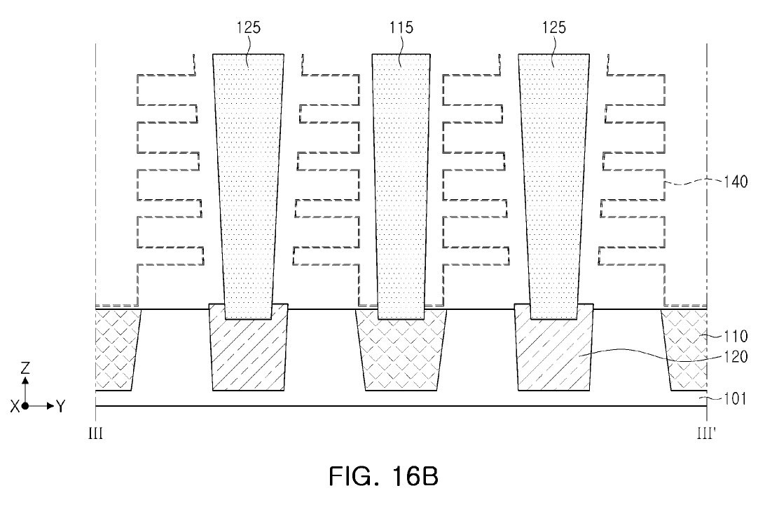

Referring to FIGS. 16A and 16B, portions of the electrodes 165 and the gate dielectric liners 163 may be selectively removed in the first direction (X-direction) through the third openings OPN3, so that the channel layer 140 may protrude in the first direction (X-direction). The channel layer 140 may protrude by a length by which each of the electrodes 165 and the gate dielectric liners 163 is removed in the first direction (X-direction). For example, each of the electrodes 165 and the gate dielectric liners 163 may be removed by about 1.5 nm to about 2.0 nm in the first direction (X-direction). In this specification, the third opening OPN3 may be referred to as a ‘source/drain trench.’

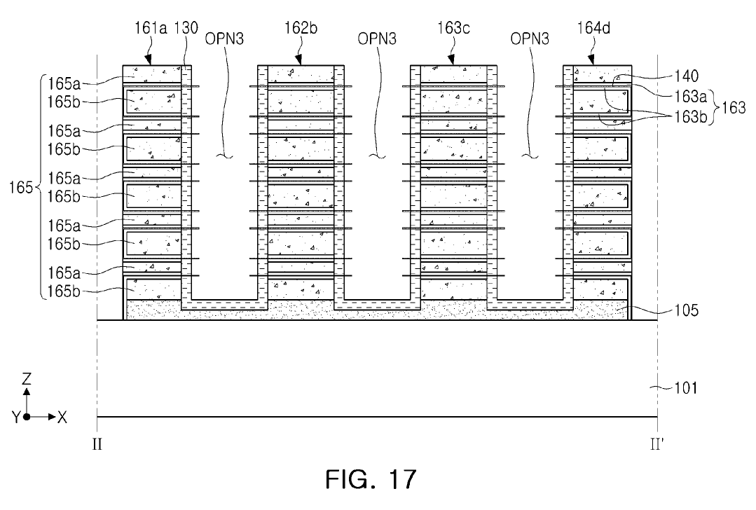

Referring to FIG. 17, a spacer layer 130 may be formed on side surfaces of the first to fourth gate electrodes 160a to 160d exposed through the third opening OPN3. The channel layer 140 may penetrate through the spacer layer 130 and may be exposed from one surface of the spacer layer 130. The spacer layer 130 may be formed by forming an insulating material layer to cover the side surfaces of the first to fourth gate electrodes 160a to 160d and the channel layer 140, and then partially removing the insulating material layer in the first direction (X-direction) so that the channel layer 140 is exposed. The spacer layer 130 may be formed of at least one of an oxide, a nitride or an oxynitride, and may be formed of a low-κ film.

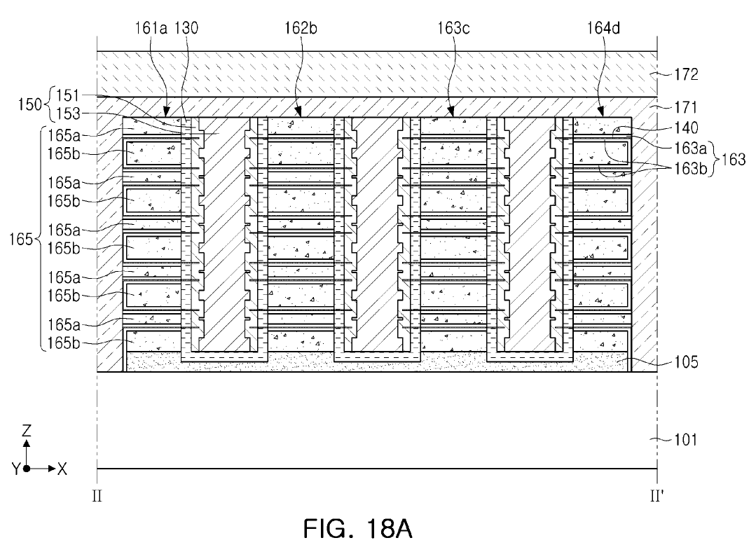

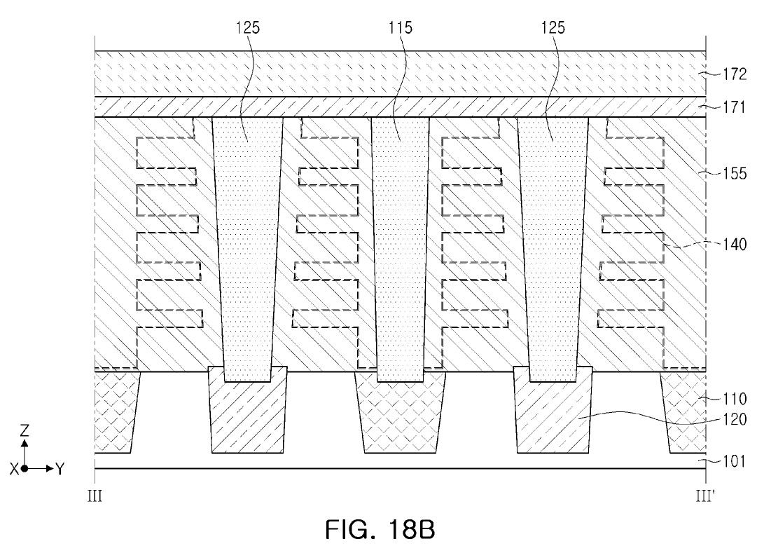

Referring to FIGS. 18A and 18B, a source/drain electrode structure 150 may be formed on the spacer layers 130. The source/drain electrode structure 150 may cover the channel layer 140 on the spacer layer 130, and a first source/drain electrode layer 151 including a first metallic material may be formed, and a second source/drain electrode layer 153 including a second metallic material different from the first metallic material may be formed on the first source/drain electrode layer 151.

A first interlayer insulating layer 171 covering the first to fourth gate electrodes 160a to 160d and the source/drain electrode structure 150 may be formed on the substrate 101 and a second interlayer insulating layer 172 may be formed on the first interlayer insulating layer 171.

Referring to FIGS. 2A, 2B and 2C together, first to fourth gate contacts 181 to 184 penetrating through the first and second interlayer insulating layers 171 and 172 and connected to the first to fourth gate electrodes 160a to 160d may be formed, and source/drain contacts 185 connected to the source/drain electrode structures 150 may be formed. Accordingly, a semiconductor device 100 may be manufactured.

A method of manufacturing a semiconductor device according to example implementations of the present disclosure may include: forming a stack structure including first sacrificial layers and second sacrificial layers alternately stacked on a substrate; forming a first sacrificial structure penetrating through a portion of the substrate and the stack structure and extending in a first direction; removing the second sacrificial layers and exposing a side surface of the first sacrificial structure through first gap regions between the first sacrificial layers; forming a first gate dielectric liner, a second gate dielectric liner and a channel layer between the first and second gate dielectric liners, on the first gap regions and the substrate; forming a first electrode on the first gate dielectric liner; removing a portion of the first sacrificial structure to form a first element isolation film within the substrate and exposing side surfaces of the first sacrificial layers; forming second gap regions by removing the first sacrificial layers; forming a second electrode on the second gap regions and the substrate; forming a first gate separation structure penetrating through the second electrode on the first element isolation film and extending in the first direction; forming a source/drain trench penetrating through the first and second electrodes and the first and second gate dielectric liners and extending in a second direction, intersecting the first direction; forming a spacer layer according to a surface profile of the source/drain trench; and forming a source/drain electrode structure on the spacer layer.

In an example implementation, the forming the first gate dielectric liner, the channel layer and the second gate dielectric liner may include: forming the second gate dielectric liner along a side surface of the first sacrificial structure exposed between the first sacrificial layers and a surface profile of the first sacrificial layers; growing the channel layer using the second gate dielectric liner as a seed layer; and forming the first gate dielectric liner on the channel layer, and the first and second gate dielectric liners may include a high-κ insulating material, and the channel layer may include a transition metal dichalcogenide (TMD) material.

In an example implementation, the spacer layer may cover side surfaces of the first and second electrodes and the first and second gate dielectric liners exposed through the source/drain trench, but may expose the channel layer.

In an example implementation, the forming the source/drain electrode structure may include: forming a first source/drain electrode layer covering side surfaces of the spacer layer and the channel layer and including a first conductive material; and forming a second source/drain electrode layer including a second conductive material different from the first conductive material on the first source/drain electrode layer.

According to an example implementation, the method of manufacturing the semiconductor device may further include: forming a second sacrificial structure penetrating through a portion of the substrate and the stack structure and spaced apart from the first sacrificial structure in the second direction, and extending in the first direction; and removing a portion of the second sacrificial structure and exposing a side surface of the stack structure and forming a second element isolation film within the substrate.

According to an example implementation, the first sacrificial structure may include a first insulating material, and the second sacrificial structure may include a second insulating material different from the first insulating material.

According to an example implementation, the method of manufacturing the semiconductor device may further include: forming a second gate separation structure penetrating through the first electrode and extending in the first direction on the second element isolation film.

According to an example implementation, an upper surface of the first gate separation structure may be coplanar with an upper surface of the second gate separation structure.

According to an example implementation, a length of the channel layer exposed through the source/drain trench in the first direction may be about 1.5 nm to about 2 nm.

According to an example implementation, the method of manufacturing the semiconductor device may further include: forming a first interlayer insulating layer covering the first and second electrodes, the first gate separation structure, and the source/drain electrode structure, and a second interlayer insulating layer on the first interlayer insulating layer; and forming gate contacts connected to the first electrode and the second electrode and a source/drain contact connected to the source/drain electrode structure by penetrating through the first and second interlayer insulating layers.

As used herein, “about,” “approximately,” “generally,” and “substantially” are understood to refer to numbers in a range of numerals, for example the range of -10% to +10% of the referenced number, preferably -5% to +5% of the referenced number, more preferably -1% to +1% of the referenced number, most preferably -0.1% to +0.1% of the referenced number. Moreover, any numerical ranges disclosed herein should be interpreted as providing support for any specific value or sub-range within the stated range. For example, a disclosure of a range from 1 to 10 supports sub-ranges such as 1 to 5, 3 to 6, 1 to 9, 2.5 to 4.7, 2.2 to 9.9, and so on.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor device comprising:
a substrate;
a gate separation structure extending in a first direction on the substrate;
gate structures extending in a second direction, intersecting the first direction, on the substrate and spaced apart from each other by the gate separation structure, in the second direction;
source/drain electrode structures on at least one side of each of the gate structures;
spacer layers between the gate structures and the source/drain electrode structures; and
channel layers extending into the spacer layers, thereby contacting the source/drain electrode structures, wherein each of the gate structures is around a periphery of the channel layers,
wherein each of the gate structures includes:
a first electrode including:
a first portion, and
first protrusion portions extending from the first portion and protruding toward the gate separation structure, wherein the first protrusion portions are spaced apart from each other in a vertical direction intersecting the first direction and the second direction; and
a second electrode including:
a second portion, and
second protrusion portions extending from the second portion and protruding between the first protrusion portions, wherein the second protrusion portions are spaced apart from each other in the vertical direction,
wherein each of the channel layers extends between the first electrode and the second electrode.

2. The semiconductor device of claim 1, wherein a first height of each of the first protrusion portions of the first electrode in the vertical direction is smaller than a second height of each of the second protrusion portions of the second electrode in the vertical direction.

3. The semiconductor device of claim 1, wherein each of the channel layers includes a two-dimensional transition metal dichalcogenide (TMD) material.

4. The semiconductor device of claim 3, wherein each of the channel layers includes molybdenum diselenide (MoSe₂) or tungsten diselenide (WSe₂).

5. The semiconductor device of claim 1, wherein each of the gate structures includes a first gate dielectric liner between the first electrode and each of the channel layers, and a second gate dielectric liner between the second electrode and each of the channel layers.

6. The semiconductor device of claim 5, wherein a thickness of the first gate dielectric liner is greater than a thickness of each of the channel layers, and a thickness of the second gate dielectric liner is greater than the thickness of each of the channel layers.

7. The semiconductor device of claim 5, wherein each of the first gate dielectric liner and the second gate dielectric liner includes a first gate dielectric layer having a first permittivity and a second gate dielectric layer having a second permittivity greater than the first permittivity.

8. The semiconductor device of claim 7, wherein each of the channel layers is in contact with the second gate dielectric layer of the second gate dielectric liner and the first gate dielectric layer of the first gate dielectric liner.

9. The semiconductor device of claim 1, wherein each of the source/drain electrode structures includes:
a first source/drain electrode layer in contact with each of the channel layers exposed from the spacer layers, and
a second source/drain electrode layer on a side surface of the first source/drain electrode layer,
wherein the first source/drain electrode layer includes a first metallic material, and
wherein the second source/drain electrode layer includes a second metallic material different from the first metallic material.

10. The semiconductor device of claim 9, wherein the first metallic material includes at least one of scandium (Sc) or niobium (Nb), and
wherein the second metallic material includes at least one of tungsten (W) or molybdenum (Mo).

11. The semiconductor device of claim 1, wherein the second electrode of each of the gate structures is in contact with the gate separation structure.

12. The semiconductor device of claim 1, wherein a width of the gate separation structure in the second direction narrows toward a lower portion of the gate separation structure.

13. The semiconductor device of claim 1, wherein a thickness of each of the channel layers is in a range of 0.65 nm to 0.7 nm.

14. A semiconductor device comprising:
a substrate;
first gate structures spaced apart from each other on the substrate in a first direction and extending in a second direction, intersecting the first direction, each of the first gate structures including:
a first electrode including first protrusion portions, and
a second electrode including second protrusion portions alternately stacked with the first protrusion portions in a vertical direction;
a first source/drain electrode structure between the first gate structures and extending in the second direction;
first spacer layers on both sides of the first source/drain electrode structure;
first channel layers between each of the first protrusion portions and each of the second protrusion portions, the first channel layers extending in the first direction and extending into the first spacer layers, thereby contacting the first source/drain electrode structure;
a first gate dielectric liner between each of the first protrusion portions and each of the first channel layers; and
a second gate dielectric liner between each of the second protrusion portions and each of the first channel layers.

15. The semiconductor device of claim 14, wherein a thickness of the first gate dielectric liner is greater than a thickness of each of the first channel layers, and a thickness of the second gate dielectric liner is greater than the thickness of each of the first channel layers.

16. The semiconductor device of claim 14, comprising:
a first gate separation structure extending into the first gate structures and extending in the first direction,
wherein each of the first gate structures includes:
a first portion, wherein the first protrusion portions are connected through the first portion, and
a second portion, wherein the second protrusion portions are connected through the second portion, and
wherein each of the first protrusion portions protrudes toward the first gate separation structure.

17. The semiconductor device of claim 14, comprising:
second gate structures spaced apart from the first gate structures on the substrate in the second direction, each of the second gate structures including third protrusion portions and fourth protrusion portions alternately stacked with the third protrusion portions in the vertical direction;
second source/drain electrode structures between the second gate structures and extending in the second direction;
second spacer layers on both sides of the second source/drain electrode structures;
second channel layers between each of the third protrusion portions and each of the fourth protrusion portions, extending in the first direction and extending into the second spacer layers, thereby contacting the second source/drain electrode structures;
a third gate dielectric liner between each of the third protrusion portions and each of the second channel layers; and
a fourth gate dielectric liner between each of the fourth protrusion portions and each of the second channel layers,
wherein the first channel layers include a first transition metal chalcogenide material, and
the second channel layers include a second transition metal chalcogenide material different from the first transition metal chalcogenide material.

18. The semiconductor device of claim 17, wherein the first transition metal chalcogenide material includes molybdenum, and
wherein the second transition metal chalcogenide material includes tungsten.

19. The semiconductor device of claim 17, comprising:
a first gate separation structure extending into the first gate structures and extending in the first direction;
a second gate separation structure extending into the second gate structures and extending in the first direction; and
an element isolation structure extending in the first direction between the first gate structures and the second gate structures,
wherein upper surfaces of the first and second gate separation structures are coplanar with an upper surface of the element isolation structure.

20. A semiconductor device, comprising:
a substrate;
a gate separation structure extending in a first direction on the substrate;
gate structures extending in a second direction, intersecting the first direction, on the substrate and spaced apart from each other by the gate separation structure in the second direction, each of the gate structures including first protrusion portions and second protrusion portions disposed alternately with the first protrusion portions;
a source/drain electrode structure on at least one side of each of the gate structures;
spacer layers between the gate structures and the source/drain electrode structure;
a first gate dielectric liner covering a side surface, an upper surface, and a lower surface of each of the first protrusion portions;
a second gate dielectric liner covering a side surface, an upper surface, and a lower surface of each of the second protrusion portions; and
a channel layer between the first gate dielectric liner and the second gate dielectric liner and in contact with the first gate dielectric liner and the second gate dielectric liner,
wherein a thickness of the first gate dielectric liner is greater than a thickness of the channel layer,
wherein a thickness of the second gate dielectric liner is greater than the thickness of the channel layer, and
wherein the channel layer includes a transition metal dichalcogenide (TMD) material.
